(19) United States
(12) Patent Application Publication
(10) Pub. No.: US 2021/0076514 A1
(43) Pub. Date: Mar. 11, 2021

(54) VEHICLE DOOR HANDLE

(71) Applicant: Huf Hülsbeck & Fürst GmbH & Co. KG, Velbert (DE)

(72) Inventors: Bernd Reifenberg, Essen (DE); Hubert Bextermöller, Muhlheim A.d.r. (DE); Dominik Behmenburg, Dusseldorf (DE); Michael Rhein, Monchengladbach (DE)

(21) Appl. No.: 16/772,182

(22) PCT Filed: Dec. 10, 2018
(86) PCT No.: PCT/EP2018/084119

§ 371 Date: Jun. 12, 2020

(30) Foreign Application Priority Data
Dec. 21, 2017 (DE) 10 2017 130 876.8

(51) Int. Cl. H05K 5/00; H01R 12/71; H01R 13/516; H05K 7/14; B60R 16/02; E05B 85/10

(52) U.S. Cl. CPC H05K 5/0069; H01R 12/71; H01R 13/516; E05Y 2900/531; B60R 16/02; E05B 85/10; H01R 2201/26; H05K 7/1427

(57) ABSTRACT

A vehicle door handle with a handle housing, wherein the handle housing is formed of at least two shell elements. At least one circuit board with electronic components is accommodated in the handle housing and coupled to an electrical connector, which is arranged outside the housing so as to make contact with the circuit board. The electrical connector has a plurality of contacts, which are connected to the circuit board via electrical cables. The circuit board is situated on a support in the handle housing and the support is formed integrally with the electrical connector as an injection-molded part. The electrical cables are overmolded as metallic conductors in the support and at least some of the metallic conductors protrude out of the injection-molded part in the region of the electrical connector and the circuit board for the purpose of making contact.

### CROSS-REFERENCE TO RELATED APPLICATIONS

This application is the national phase of International Application No. PCT/EP2018/084119, filed Dec. 10, 2018, which claims priority to DE Application Serial No. 10 2017 130 876.8, filed Dec. 21, 2017, the contents of which are hereby incorporated by reference in their entireties.

### FIELD

The present disclosure relates to a vehicle door handle for doors or hatches of motor vehicles.

### BACKGROUND

This section provides background information related to the present disclosure and is not necessarily prior art. Vehicle door handles of the type mentioned are used in vehicles in order to provide mechanical means for actuating a door or hatch and also communication functions and/or switching functions.

For example, EP 2 607 581 A2 describes a vehicle door handle of the type mentioned above. With this vehicle door handle, electronic components are embedded in a multi-shell handle housing with a casting compound. An electrical connector is arranged so that it is accessible outside the handle housing in order to couple the electronic components inside the housing to an electronic control system of the vehicle.

Vehicle door handles of the type mentioned are complex to manufacture and assemble. The flexible cable components between the electrical connector and the circuit board make it difficult to align the components within the door handle and to arrange the cables in the handle.

### SUMMARY

This section provides a general summary of the disclosure, and is not a comprehensive disclosure of its full scope or all of its features. The object of the disclosure is to provide an inexpensive and easy-to-assemble vehicle door handle system.

One aspect of the disclosure provides a vehicle door handle. The vehicle door handle has a handle housing which is formed from at least two shell components. At least one circuit board is accommodated in the handle housing and equipped with electronic components. The electrical components can in particular have sensors, switches, antennas and communication circuits. An electrical connector is coupled to the vehicle door handle, which is provided for making contact with the circuit board and the electronic components arranged thereon and is arranged outside the housing in order to provide an electrical interface for a corresponding connector on the vehicle side. The electrical connector has a plurality of contacts, which in turn are coupled to electrical lines, the lines extending from the contacts of the electrical connector through the handle inside to the circuit board.

The vehicle door handle is characterized in that the circuit board with the electronic components and a carrier is arranged and fixed in the handle housing, the carrier being formed integrally with the electrical connector as an injection molded part. The circuit board is therefore not attached to the electrical connector by flexible cable connections, but the electrical connector is integrally manufactured together with the carrier as a continuous injection molded part. The electrical connector can then be considered as a section of the carrier. This means that the carrier and the electrical connector are in a defined and unchangeable position and orientation to each other. The integral design also eliminates any risk of the electrical connector twisting relative to the carrier.

The carrier provides a receptacle for the circuit board and uses this receptacle to fix the circuit board in a specified position with respect to the carrier and thus also with respect to the electrical connector.

Furthermore, the electrical lines between the electrical connector and the circuit board, which are arranged in the carrier, are designed as metallic conductors, which are overmolded in the carrier. These metallic conductors protrude from the injection molded part of the carrier in the region of the electrical connector and in the region of the circuit board for making contact.

As for the circuit board, it is fixed on the carrier, and is coupled to the protruding sections of the electrical conductors, and on the side of the electrical connector, sections of the electrical lines protrude for contacting via a corresponding electrical connector on the vehicle.

The electrical lines are insulated by being accommodated in the injection molded part itself and fixed in their position in relation to the carrier. No cable guides are required to connect the connector and the circuit board; instead, the electrical cables overmolded in the carrier serve as electrical signal and supply paths.

In the manufacture of the carrier in an injection molding process, the positional relationships between the electrical connector and the contacts for the circuit board are fixed by overmolding the electrical lines, the lines are isolated from one another and from the environment, and reproducible positional relationships between the contacts and the circuit board are provided. The electrical lines can be designed as strands, sheets or wires. Die-cut and curved sheets are particularly suitable, which can be produced with several lines in one process step. Up to the step of overmolding, these lines can be held in a desired alignment with each other before the injection molding material fixes them in place. The spacers can then remain in their position, provided that they do not cause galvanic coupling of the lines or are pierced with appropriate tools, so that any galvanic coupling of the conductors to each another is prevented. The use of the carrier, the circuit board accommodated on it and the electrical cables in the carrier in the handle housing enables the position of the electrical connector relative to the handle housing as well as the circuit board in the handle housing to be reproducibly ensured with reliable electrical contact at all times.

The inventive production of the carrier and the integrally molded electrical connector in one process step makes the component particularly cost-effective and at the same time reduces rejects, since the electrical conductors can be routed from the electrical connector through the carrier to the circuit board without intermediate contact. It is not necessary to connect a plug to cables, e. g., by soldering or crimping, which then lead to the circuit board.

In at least one implementation, the electrical lines are designed as a punched and bent metal structure with at least two spaced-apart conductor paths.

The production of the lines by punching and bending creates a self-supporting and stable ladder structure, which is adapted to the shape of the resulting injection molded part and which, after initially being placed, is held in a die for the injection molding process. By punching and bending, several conductor paths can be formed and adapted to the shape of the injection molded part formed simultaneously in one process step.

Corresponding punching tools and bending devices are available in the art and the resulting electrical lines are regularly cheaper than stranded wires or wire lines. Conductive metal sheets are used as materials.

In at least one implementation, the carrier of the vehicle door handle has a receptacle for the circuit board, which has a means for clipping or latching. Equipping the carrier with clipping or latching means, which encompass the circuit board or come into play at designated points, allows the circuit board to be mounted extremely quickly and securely on the carrier. The locking means and clips can in particular be formed integrally with the carrier itself from the injection-molded material of the carrier, so that no further means are required for fixing the circuit board.

The circuit board is preferably provided with a plurality of continuous openings which accommodate and make contact with the metallic conductors protruding from the support. The sections of the metallic conductor protruding from the carrier run through the openings in the circuit board when it is placed on the carrier and fixed there. The metallic conductors can then be galvanically coupled with contacts at the continuous openings, e.g. by soldering or bending. In this way, the sections of the metallic conductors protruding from the carrier lead to an even more reproducible alignment of the circuit board on the carrier, since it can be arranged at any time in such a way that the protruding sections of the conductor extend through the associated openings.

In at least one implementation, the carrier has support attachments which are supported on the inside of at least one of the shell components and fix the carrier with the circuit board attached thereon in the shell component, e.g. by jamming. The support attachments ensure that the support is accommodated free from play and secure in a reproducible position in the housing by supporting it on at least one shell component. In addition, in the event that the support attachments protrude from the carrier in relation to the circuit board, the support attachments can prevent the circuit board from resting against the handle shells and, for example for subsequent casting of the components in the handle, bring the circuit board into a designated position and fix it there. The support attachments can be designed for clamping and locking the carrier in a grip shell, so that the carrier is fixed in corresponding receptacles of the grip shells after being pressed into its mounting position by clamping forces or by snapping the support attachments into place.

In addition, in at least one implementation, one of the metallic conductors is exposed in a section between the electrical connector and the circuit board, thus protruding from the injection molded component of the carrier and contacting an interior of one of the shell components. Such contacting can be desired, for example, to produce a galvanic coupling of electronic components on the circuit board and the handle shell, which e.g. is chrome coated.

In the aforementioned preferred exemplary embodiment, the exposed metallic conductor for making contact with one of the handle shells can also be galvanically coupled to a spring, in particular a conductive leaf spring, so that when the handle shells are assembled, the leaf spring rests on the inside against one of the handle shells and produces the galvanic coupling.

It is particularly preferred that the carrier is formed in a section between the electrical connector and the circuit board with one or more angled sections, so that the carrier can overlap a wall of one of the shell components there, and becomes immersed into the shell component on the inside of the shell component. Such an angled configuration allows the carrier to be inserted into a shell component and to be immersed there in such a way that the carrier together with the circuit board located thereon is in a moldable cavity. The angled section of the carrier then overlaps a wall which forms a boundary of the casting space, so that the casting is ensured, but at the same time the electrical connector is arranged outside the housing. The section in the interior of the shell component is then below the fill level of the casting compound, the angled section protrudes from the casting compound and overlaps the wall in order to extend outside the shell component to the integrally formed electrical connector. The metallic conductors molded in the carrier follow the angled sections, i.e. they are provided with the appropriate angles and bends, for example by bending processes, and thus also overlap the lateral limitation of the handle shells.

It is particularly preferred that one of the shell components of the handle housing has a receptacle for the electrical connector, so that the electrical connector can be latched or clipped into the electrical connector receptacle when the carrier is inserted into the housing and is fixed there in its end position.

A receptacle that accommodates and fixes the electrical connector on one of the shell components is advantageous since such a mechanical support protects the material of the carrier and integrally formed electrical connector during the connection process with an electrical connector on the vehicle. In addition, such a system is particularly compact and is very easy to store, since there are no loose electrical connectors that could get caught or tangled when stored with other components if the handle is stored together with other components.

It is particularly advantageous if the electrical connector extends in a housing attachment which is designed to mechanically couple the vehicle door handle to a handle carrier in a vehicle. Vehicle door handles have one or two attachments that pass through a vehicle panel when mounted on the vehicle and are coupled to a handle carrier or other structure on the inside of the door panel. If the electrical connector is designed such that it extends in one of these mechanical coupling sections of the door handle, the electrical connector is guided through the door panel of the vehicle at the same time as the mechanical coupling section when it is mounted on the vehicle. An electrical coupling can then be established on the inside between the electrical connector and the vehicle system. Further areas of applicability will become apparent from the description provided herein. The description and specific examples in this summary are intended for purposes of illustration only and are not intended to limit the scope of the present disclosure.

### DRAWINGS

The invention will now be explained in more detail with reference to the accompanying drawings. The drawings described herein are for illustrative purposes only of selected configurations and not all possible implementations, and are not intended to limit the scope of the present disclosure. Corresponding reference numerals indicate corresponding parts throughout the drawings.

FIG. 1a shows an assembled handle according to a first embodiment of the invention in a first view;

FIG. 1b shows the handle from FIG. 1a in a second view;

FIG. 2a shows a partially assembled handle according to the first embodiment with a casted circuit board;

FIG. 2b shows a partially assembled handle according to the first embodiment without casting compound;

FIG. 3a shows the assembled handle according to the first embodiment in plan view;

FIG. 3b shows the partially assembled handle according to the first embodiment in plan view with a casted circuit board;

FIG. 3c shows the partially assembled handle according to the first embodiment in plan view without casting compound;

FIG. 4a shows a carrier arranged in a handle according to the first embodiment with a circuit board arranged thereon;

FIG. 4b shows the carrier from FIG. 4a with the circuit board removed;

FIG. 4c shows the carrier from FIGS. 4a and 4b with detached circuit board and separately shown punched and bent electrical lines;

FIG. 5a shows the carrier with the circuit board arranged thereon in plan view from above;

FIG. 5b shows the carrier without a circuit board arranged thereon in plan view;

FIG. 5c shows the carrier in plan view and in a partially transparent illustration to illustrate the course of the electrical lines in the carrier;

FIG. 6a shows the punched and bent electrical lines for overmolding in the carrier;

FIG. 6b shows a partial section of the carrier produced by injection molding with electrical lines arranged therein;

FIG. 6c shows the carrier from FIG. 6b in a partially transparent illustration;

FIG. 7a shows a partially assembled illustration of the handle according to the first embodiment with the carrier mounted completely in the handle;

FIG. 7b shows a sectional view of the carrier from FIG. 7a to show the electrical connector clipped onto the handle;

FIG. 8a shows the assembled handle according to the first embodiment in a view from behind (from the vehicle side);

FIG. 8b shows the carrier from the vehicle door handle of view 8a with a circuit board arranged thereon; and

FIG. 8c shows the carrier from the vehicle door handle of view 8a without a circuit board.

### DETAILED DESCRIPTION

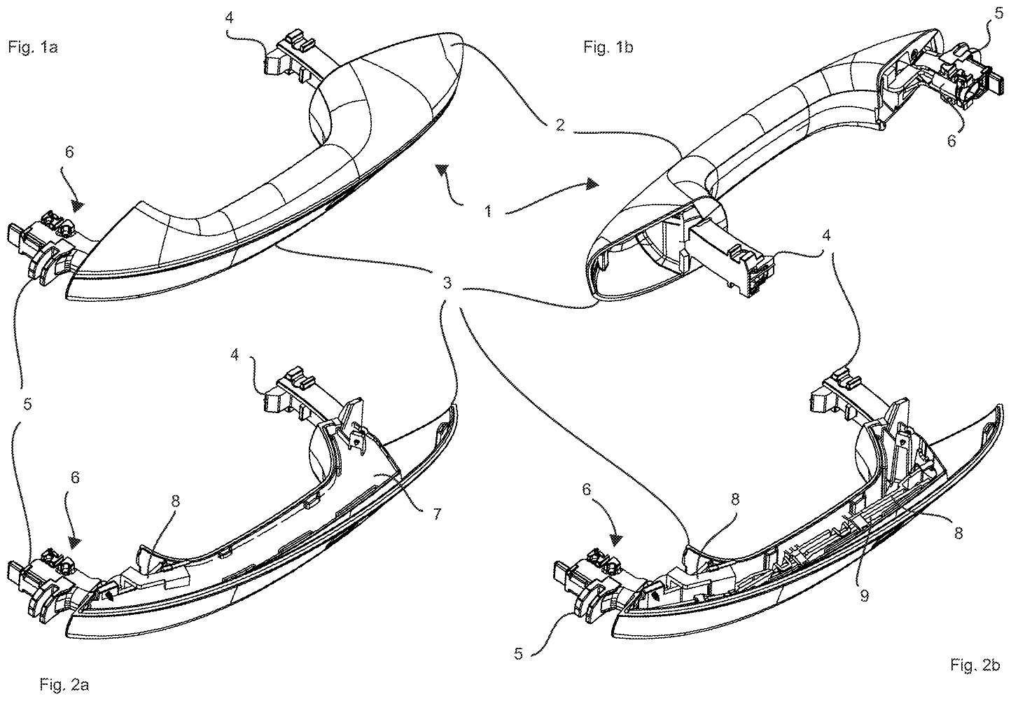

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure. FIG. 1 shows a motor vehicle door handle 1 according to a first embodiment of the invention. Handle 1 has an upper shell component 2 and a lower shell component 3, which are connected during assembly of the handle in order to form the handle of the motor vehicle door handle 1. Mechanical coupling attachments 4 and 5 are also formed on motor vehicle door handle 1. These mechanical coupling attachments 4 and 5 protrude through recesses in a vehicle door panel when mounting vehicle door handle 1 and are coupled to a handle carrier on the inside of the vehicle door panel, so that vehicle door handle 1 is mounted on the door and is coupled for mechanical actuation of locking components on the vehicle side. An electrical connector 6 is accommodated in mechanical coupling section 5 and will be explained in detail below.

FIG. 2a shows the handle from FIGS. 1a and 1b, with shell component 2 removed. It can be clearly seen in this illustration that shell components 2 and 3 delimit a cavity in which further components are accommodated. In particular, casting compound 7 is shown in FIG. 2a, which fills the trough-shaped interior of shell component 3. This casting compound is poured into the shell component 3 in liquid form in order to protectively enclose the components therein, in particular carrier 8 and a circuit board 9 with electrical components located thereon. After curing, casting compound 7 protects the components arranged in shell component 3 against the effects of weather and mechanical damage and locks them in place. FIG. 2a also shows a section of carrier 8 which protrudes from casting compound 7. The visible section of carrier 8 overlaps a wall of shell component 3 with an angled section. In this way it is possible to make the wall for the casting in shell component 3 higher, since carrier 8 overlaps the wall through angled sections.

In FIG. 2b, casting compound 7 has been removed from the illustration in FIG. 2a, so that the components arranged in shell component 3 are visible. Carrier 8 with a circuit board 9 arranged thereon is accommodated in shell component 3. Carrier 8 is supported on the inside of shell component 3 on the walls thereof, so that carrier 8 is fixed in its position in shell component 3.

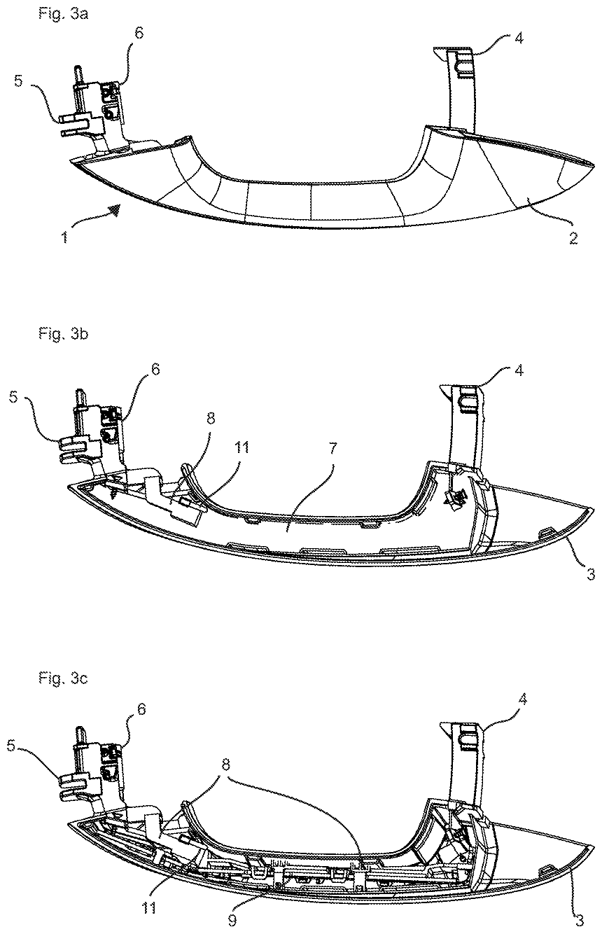

FIGS. 3a, 3b and 3c show illustrations corresponding to FIGS. 1a, 2a, 2b, but in a different view. FIG. 3a shows motor vehicle door handle 1 in a closed and fully assembled form, that is to say with shell component 2 attached. In FIGS. 3b and 3c, shell component 2 is removed, so that lower shell component 3 is exposed. In FIG. 3b, in turn, the interior of shell component 3 is filled with casting compound 7, carrier 8 protruding in sections from casting compound 7 and overlapping a wall of shell component 3 and extending as far as electrical connector 6 with which it is integrally formed. FIG. 3c shows this view, but without casting compound 7.

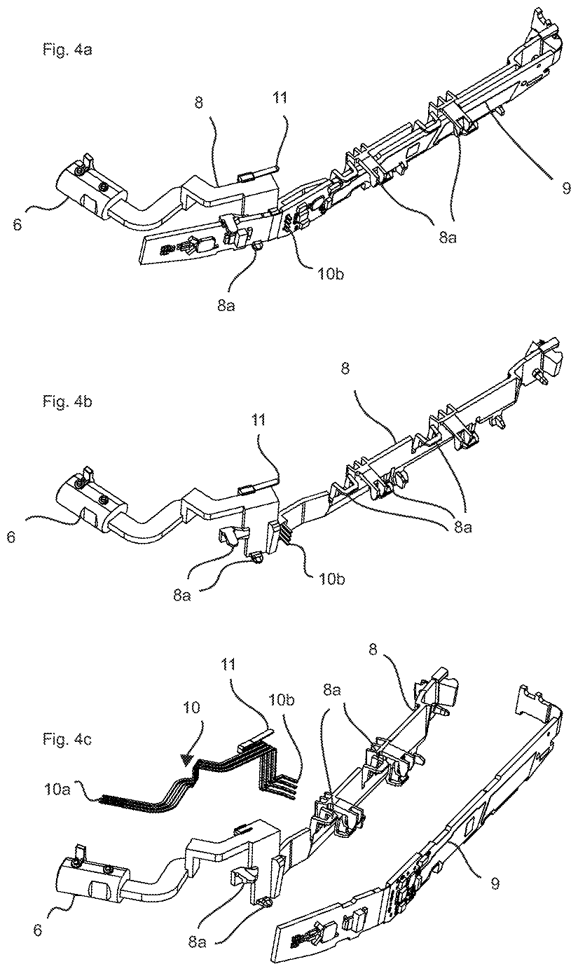

FIG. 4a shows carrier 8 alone, which is made of an injection molding material and has an integrally molded electrical connector 6. Circuit board 9 is held by holding means 8a which are formed integrally with carrier 8. In carrier 8, electrical lines 10 extend from electrical connector 6 to circuit board 9, which protrude in the region of the circuit board with sections 10b from carrier 8 and are guided through recesses into circuit board 9. There they are galvanically connected to corresponding contacts on the feed-through for contacting circuit board 9. In the region of electrical connector 6, sections 10a protrude in the electrical connector for making contact.

In FIG. 4b, both holding means 8a in the shape of clips on carrier 8 can be seen more clearly, and thus also end sections 10b of electrical lines 10, since in this illustration circuit board 9 has been removed.

FIG. 4c shows carrier 8 with integrally molded electrical connector 6, and in addition, electrical lines 10 are displaced from the inside of carrier 8 for clarification. It can be seen that lines 10 are designed as spaced-apart, punched and bent electrical sheets which match the outer shape of injection-molded carrier 8. In particular, electrical lines 10 in their punched and curved shape have the same angles, which enable carrier 8 to be lowered in sections into shell component 3 and to overlap it in the region of its wall, so that the molded electrical connector 6 can be accommodated in mechanical coupling attachment 5. In this illustration it can also be seen that one of the conductor tracks of electrical lines 10 does not run from the circuit board to electrical connector 6, but is coupled in a section between electrical connector 6 and circuit board 9 to a leaf spring 11. This leaf spring is guided to the outside on the upper side of carrier 8 and makes contact with the inside of shell component 2 there when it is placed on to close the handle. The inside of shell component 2, which can in particular be chrome-plated, is thus coupled to circuit board 9 via electrical lines 10.

In this exemplary embodiment, electrical lines 10 are formed by punching and bending as a self-supporting plurality of spaced-apart and parallel conductor paths. This arrangement of conductors can be arranged in an injection mold in which carrier 8 with electrical connector 6 is formed by overmolding, electrical lines 10 with sections 10a, 10b protruding from the tool in the region of electrical connector 6 and in the region of the circuit board and are not overmolded.

For the process of overmolding, the lines can be held in correct alignment with one another by non-conductive spacers. Alternatively, electrical lines 10 can also be connected by conductive spacers before the overmolding process, which are detached by an appropriate tool after the overmolding process.

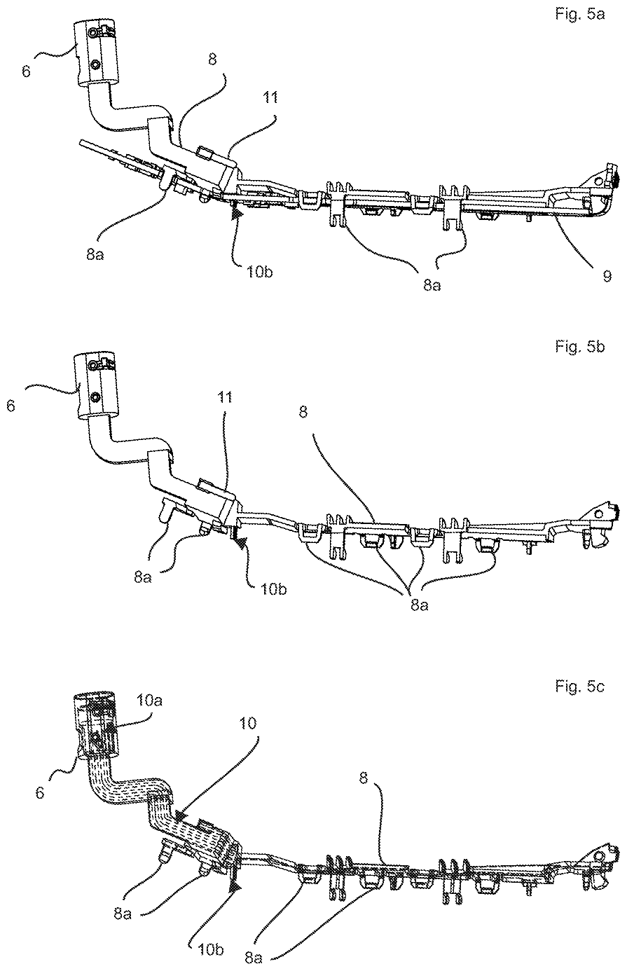

FIGS. 5a, 5b and 5c correspond to illustrations 4a and 4b, but show carrier 8 and circuit board 9 in plan view. FIG. 5c shows carrier 8 with its injection molding material in a partially transparent manner, so that the course of electrical contacts 10 through the injection molding material is shown in a traceable manner from electrical connector 6 to the side of the circuit board.

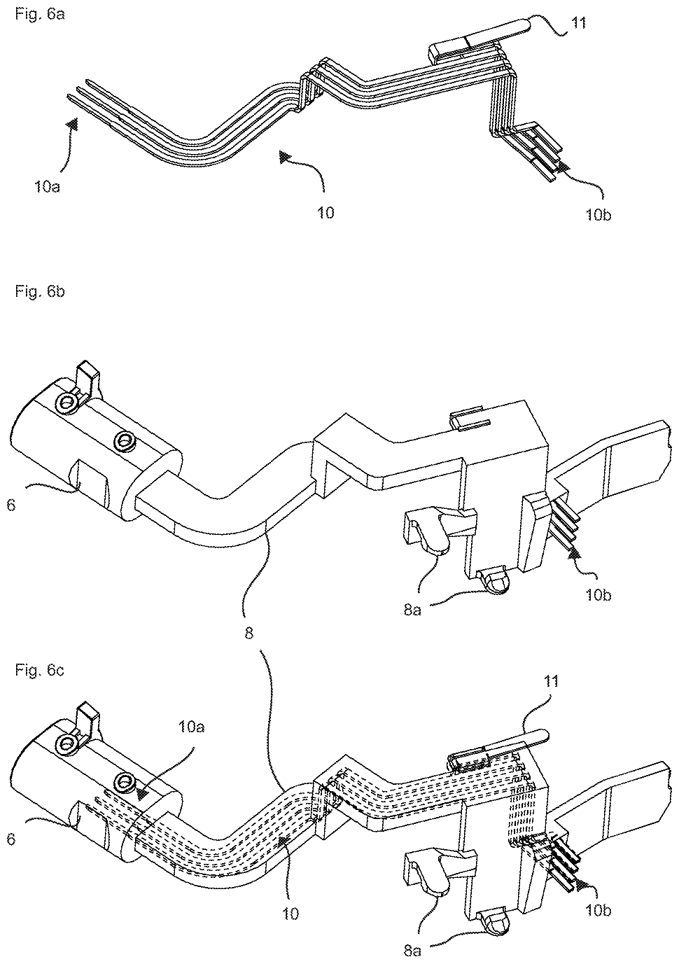

FIGS. 6a, 6b and 6c show the enlargements of the carrier section and the associated electrical lines in the region in which electrical lines 10 extend through carrier 8.

FIG. 6a shows insulated electrical lines 10 with coupled leaf spring 11, as they are designed to be accommodated in carrier 8. At the end, contact connections 10a, 10b are formed, which on the one hand are led out of the injection-molded part of carrier 8 in electrical connector 6 for making contact and on the other end protrude from carrier 8 in order to make contact with circuit board 9. FIG. 6c shows carrier 8 with cast-in electrical lines 10, with electrical lines 10 shown as dashed lines in the regions which are surrounded by the material of carrier 8. This illustration shows the course of the electrical lines in the injection molded body. In this illustration, it is not readily apparent that electrical connector 6 is designed as a hollow body with a a free interior space for accommodating s complementary plug, so that connections 10a of electrical lines 10 are exposed in a manner conducive to making contact inside electrical connector 6.

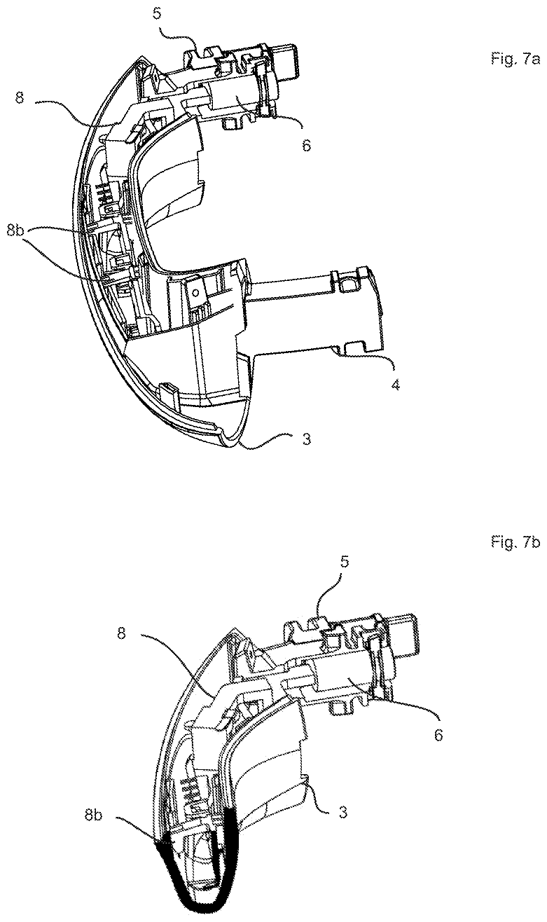

Like the sectional illustration in FIG. 7b, FIG. 7a shows the handle according to the first exemplary embodiment with shell component 2 removed, in order to illustrate the arrangement of carrier 8 and integrally designed electrical connector 6 in the handle. It can be seen that electrical connector 6 is laterally inserted into a recess of the handle, in particular in a free space of mechanical coupling part 5, and is available there for making contact with a plug. In addition, it can be seen in FIG. 7b that support attachments 8b are supported on the inside on the wall of shell component 3 in order to ensure that the carrier is securely positioned in shell component 3 until the components have been cast in shell component 3.

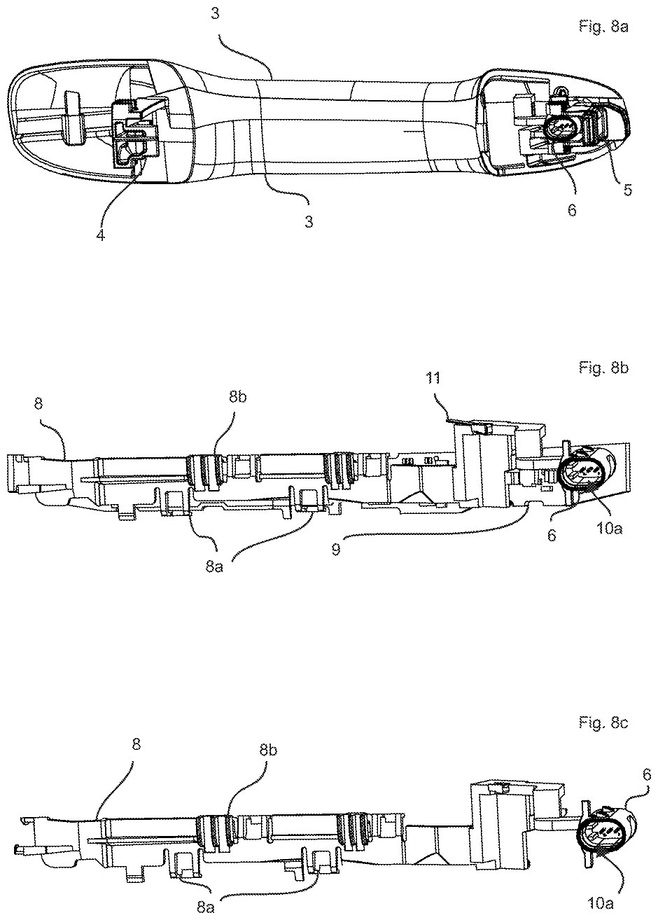

FIGS. 8a, 8b and 8c finally show the first embodiment according to the invention in a further view, which shows the mounted handle in FIG. 8a. FIG. 8b shows carrier 8 with an integrally molded electrical connector 6, the exposed contact sections 10a in electrical connector 6 being visible in this illustration. FIG. 8b shows the carrier with the circuit board clipped onto it. Finally, FIG. 8c shows the carrier without the circuit board clipped on.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

1. A vehicle door handle with comprising:
a handle housing formed from at least two shell components;
a circuit board equipped with electronic components and accommodated in the handle housing; and
an electrical connector, arranged outside the housing for making contact with the circuit board, the electrical connector having a plurality of contacts coupled to electrical lines extending into the housing and to the circuit board,
wherein the circuit board is arranged and fixed on a carrier in the handle housing, the carrier and the electrical connector being formed integrally as an injection-molded part, and
wherein the electrical lines in the carrier are overmolded as metallic conductors and at least some of the metallic conductors protrude from the injection molded part in the region of the electrical connector and the circuit board for making contact.

2. The vehicle door handle according to claim 1, wherein the electrical lines are formed as a punched and bent metal structure with at least two spaced apart conductor paths.

3. The vehicle door handle according to claim 1, wherein the carrier includes a receptacle for accommodating the circuit board, the receptacle holding the circuit board with a clip or latching on the carrier.

4. The vehicle door handle according to claim 1, wherein the circuit board includes a plurality of continuous openings which accommodate and contact the metallic conductors protruding from the carrier.

5. The vehicle door handle according to claim 1, wherein the carrier has support attachments which are supported on the inside of at least one of the shell components and fix the carrier with the circuit board in the shell component.

6. The vehicle door handle according to claim 1, wherein at least one of the metallic conductors protrudes from the carrier in a section between the electrical connector and the circuit board and makes contact with an interior of one of the shell components.

7. The vehicle door handle according to claim 6, wherein a conductive leaf spring is galvanically coupled to the metallic conductor for making contact with the interior of one of the shell components.

8. The vehicle door handle according to claim 1, wherein the carrier has an angled section in a section between the electrical connector and the circuit board, and wherein the carrier with the angled section overlaps a wall of a shell component and becomes immersed into the shell component from one side of the wall.

9. The vehicle door handle according to claim 1, wherein one of the shell components includes a receptacle for the electrical connector, the electrical connector being latched or clipped into the electrical connector receptacle when the carrier is inserted into the housing.

10. The vehicle door handle according to claim 1, wherein the electrical connector extends in a housing attachment for mechanically coupling the vehicle door handle to a handle carrier in a vehicle.
